(19) United States
(12) Patent Application Publication
(10) Pub. No.: US 2020/0411946 A1
(43) Pub. Date: Dec. 31, 2020

(54) ANTENNA DEVICE AND ON-BOARD EQUIPMENT

(71) Applicant: AAC Technologies Pte. Ltd., Singapore City (SG)

(72) Inventor: Yachuan Shen, Shenzhen (CN)

(21) Appl. No.: 16/993,293

(22) Filed: Aug. 14, 2020

Related U.S. Application Data
(63) Continuation of application No. PCT/CN2019/094081, filed on Jun. 30, 2019.

(51) Int. Cl. H01Q 1/12; H01Q 1/48; H01Q 9/04; H05K 1/02

(52) U.S. Cl. CPC H01Q 1/12; H01Q 1/48; H05K 2201/09036; H05K 1/0243; H05K 2201/10098; H01Q 9/0407

(57) ABSTRACT

An antenna device, including: a substrate, a ground and an antenna provided on two surfaces of the substrate; the antenna includes a first radiating portion, a second radiating portion, a one-to-two power divider and a feeding portion; the first radiating portion is provided with a first impedance adjusting groove, the other end of the first transmission wire is inserted into the first impedance adjusting groove and connected to the first radiating portion, to form two symmetrically distributed first impedance adjusting sub-grooves; the second radiating portion is provided with a second impedance adjusting groove, the other end of the second transmission wire is inserted into the second impedance adjusting groove and connected to the second radiating portion, to form two symmetrically distributed second impedance adjusting sub-grooves. The above antenna device has a simple structure, can realize directional radiation of the antenna, and also has a relatively wide radiation range.

### TECHNICAL FIELD

The present invention relates to the field of antenna technology and, in particular, to an antenna device and an on-board equipment.

### BACKGROUND

With the continuous development of mobile communication technology, the 5G era is coming. In theory, transmission speed of 5G network is hundreds of times faster than that of 4G network. For example, a 1G movie can be completely downloaded in 8 seconds under the 5G network.

Since 5G has relatively strict requirements on a size of the antenna, if the antenna is designed to be relatively large, a terminal equipment will also become larger, and in many application scenarios, directional radiation antennas need to be designed.

### SUMMARY

In view of this, an embodiment of the present invention provides an antenna device and an on-board equipment which have a simple structure, are capable of directional radiation, and have a relatively wide radiation range in a radiation direction.

A first aspect, an antenna device is provided, including:

a substrate, a ground provided on one surface of the substrate, and an antenna provided on the other surface of the substrate and comprising a first radiating portion, a second radiating portion, a one-to-two power divider and a feeding portion,

the one-to-two power divider comprises a first transmission wire, a second transmission wire, and a third transmission wire connected to the feeding portion, the first transmission wire and the second transmission wire extending in opposite directions from an end of the third transmission wire facing away from the feeding portion;

the first radiating portion is provided with a first impedance adjusting groove, and an end of the first transmission wire is inserted into the first impedance adjusting groove and connected to the first radiating portion, to form two symmetrically distributed first impedance adjusting sub-grooves; and

the second radiating portion is provided with a second impedance adjusting groove, and an end of the second transmission wire is inserted into the second impedance adjusting groove and connected to the second radiating portion, to form two symmetrically distributed second impedance adjusting sub-grooves.

As an improvement, the substrate is a PCB substrate.

As an improvement, a material of the PCB substrate is a millimeter wave dielectric material.

As an improvement, the PCB substrate is a RO4835T laminated board.

As an improvement, the PCB substrate has a thickness smaller than or equal to 1 mm.

As an improvement, the first impedance adjusting sub-groove is square or rectangular, and the second impedance adjusting sub-groove is square or rectangular.

As an improvement, the first radiating portion is square or rectangular, and the second radiating portion is square or rectangular.

As an improvement, the antenna device operates in a millimeter wave frequency band.

A second aspect, an on-board equipment is provided, the on-board equipment includes the antenna device as described in the first aspect.

The implementation of the embodiment of the present invention will have following beneficial effects:

The above antenna device includes a substrate, a ground provided on one surface of the substrate, and an antenna provided on the other surface of the substrate; the antenna includes a first radiating portion, a second radiating portion, a one-to-two power divider and a feeding portion; the one-to-two power divider includes a first transmission wire, a second transmission wire, and a third transmission wire connected to the feeding portion, the first transmission wire and the second transmission wire extending in opposite directions from an end of the third transmission wire facing away from the feeding portion; the first radiating portion is provided with a first impedance adjusting groove, and an end of the first transmission wire is inserted into the first impedance adjusting groove and connected to the first radiating portion, to form two symmetrically distributed first impedance adjusting sub-grooves; and the second radiating portion is provided with a second impedance adjusting groove, and an end of the second transmission wire is inserted into the second impedance adjusting groove and connected to the second radiating portion, to form two symmetrically distributed second impedance adjusting sub-grooves. It can be seen that the above antenna device has a simple structure and can meet the requirements for miniaturization of the terminal equipment, and the above antenna device can also achieve better directional radiation of the antenna and has a relatively wide radiation range in a radiation direction.

### BRIEF DESCRIPTION OF DRAWINGS

Many aspects of the exemplary embodiment can be better understood with reference to the following drawings. The components in the drawings are not necessarily drawn to scale, the emphasis instead being placed upon clearly illustrating the principles of the present invention. Moreover, in the drawings, like reference numerals designate corresponding parts throughout the several views.

FIG. 1 is a schematic diagram of an antenna device 100 in accordance with an embodiment of the present invention;

FIG. 2 is a schematic diagram of an antenna 30 in accordance with an embodiment of the present invention;

FIG. 3 is a diagram showing return loss of an antenna device 100 in accordance with an embodiment of the present invention;

FIG. 4 is a diagram showing radiation efficiency of an antenna device 100 in accordance with an embodiment of the present invention;

FIGS. 5 to 8 show patterns of an antenna device 100 in accordance with an embodiment of the present invention; and

FIG. 9 is a structural diagram of composition of an on-board equipment 200 in accordance with an embodiment of the present invention.

### DESCRIPTION OF EMBODIMENTS

In order to make the objectives, technical solutions and advantages of the present invention clearer, the present invention will be described in further detail below with reference to the accompanying drawings and embodiments. It should be understood that the specific embodiments described herein are only used to explain the present invention but are not used to limit the present invention.

Unless otherwise defined, all technical and scientific terms used herein have the same meaning as commonly understood by those skilled in the technical field of the present invention. The terms used in the description of the present invention herein are only for the purpose of describing specific embodiments and not intended to limit the present invention.

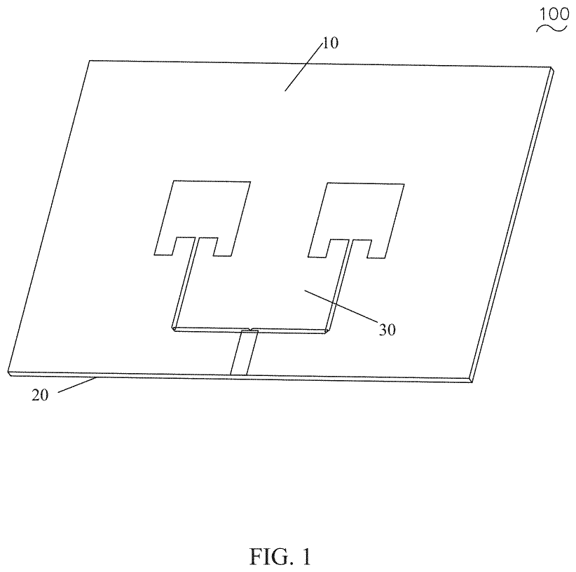

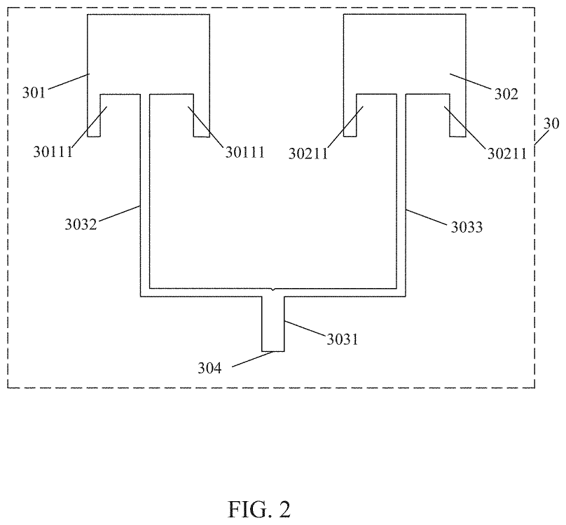

In an embodiment, an antenna device 100 is provided. As shown in FIG. 1 and FIG. 2, FIG. 1 is a schematic diagram of the antenna device 100, and FIG. 2 is a schematic diagram of the antenna 30. The antenna device 100 includes: a substrate 10, a ground 20 provided on one surface of the substrate 10, and an antenna 30 provided on the other surface of the substrate 10.

The antenna 30 includes a first radiating portion 301, a second radiating portion 302, a one-to-two power divider 303, and a feeding portion 304.

The one-to-two power divider 303 includes a third transmission wire 3031 connected to the feeding portion 304, a first transmission wire 3032 and a second transmission wire 3033 that extend in opposite directions from an end of the third transmission wire 3031 facing away from the feeding portion 304.

The first radiating portion 301 is provided with a first impedance adjusting groove 3011, the other end of the first transmission wire 3032 is inserted into the first impedance adjusting groove 3011 and connected to the first radiating portion 301, and two symmetrically distributed first impedance adjusting sub-grooves 30111 are formed by inserting the other end of the first transmission wire 3032 into the first impedance adjusting groove 3011.

The second radiating portion 302 is provided with a second impedance adjusting groove 3021, the other end of the second transmission wire 3033 is inserted into the second impedance adjusting groove 3021 and connected to the second radiating portion 302, and two symmetrically distributed second impedance adjusting sub-grooves 30211 are formed by inserting the other end of the second transmission wire 3033 into the second impedance adjusting groove 3021.

The one-to-two power divider 303 divides electrical signals fed by the feeding portion 304 into two paths, one path is directed to the first radiating portion 301 through the first transmission wire 3032, and the other path is directed to the second radiating portion 302 through the second transmission wire 3033.

The third transmission wire 3031 may be formed by connecting ends of the first transmission wire 3032 and the second transmission wire 3033 to each other, or can also be a relatively short individual transmission wire additionally provided at ends of the first transmission wire 3032 and the second transmission wire 3033.

Since the two first impedance adjusting sub-grooves 30111 and the two second impedance adjusting sub-grooves 30211 are symmetrically distributed, radiation of the antenna device 100 on left and right sides of the radiation direction is relatively balanced.

The substrate 10 is configured to carry the antenna 30. The substrate 10 may specifically be a PCB substrate, which is not specifically limited herein.

One surface of the substrate 10 is completely covered with copper foil, to form the ground 20. One surface of the antenna 30 facing away from the ground 20 is also completely covered with copper foil. Exemplarily, the antenna 30 covered with copper foil may be exposed by etching the other surface of the substrate 10.

A material of the PCB substrate may be a millimeter wave dielectric material. By choosing the millimeter wave dielectric material, high-frequency requirements of the antenna can be better met.

The PCB substrate may be a RO4835T laminated board. The RO4835T laminated board is a high-frequency board produced by Rogers Inc., and it can reduce high-speed signal transmission loss, has a stable dielectric constant and has oxidation resistance capable of reaching 10 times of a material of an ordinary PCB substrate.

A thickness of the PCB substrate is smaller than or equal to 1 mm. For high-frequency antennas, it is better to set the thickness of a dielectric plate to ⅛ of its wavelength, in order to make the antenna device 100 work better at 28 GHz, it is better that the thickness of the PCB substrate is smaller than or equal to 1 mm through mathematical calculation.

The impedance adjusting sub-grooves (the first impedance adjusting sub-groove 30111, the second impedance adjusting sub-groove 30211) are configured to adjust the antenna impedance. Sizes and shapes of the first impedance adjusting sub-groove 30111 and the second impedance adjusting sub-groove 30211 are exactly the same, and when the sizes and shapes of the impedance adjusting sub-grooves are different, the obtained antenna impedance will be different. The first impedance adjusting sub-groove 30111 may be square or rectangular, the second impedance adjusting sub-groove 30211 may also be square or rectangular. The sizes and shapes of the first impedance adjusting sub-groove 30111 and the second impedance adjusting sub-groove 30211 are not specifically limited herein and can be determined according to actual requirements of the antenna device 100.

The radiating portions (the first radiating portion 301, the second radiating portion 302) are configured to radiate and receive electromagnetic wave signals, and sizes and shapes of the first radiating portion 301 and the second radiating portion 302 are completely the same. The first radiating portion 301 may be square or rectangular, the second radiating portion 302 may also be square or rectangular. The specific shapes of the first radiating portion 301 and the second radiating portion 302 are not specifically limited herein and can be determined according to actual requirements of the antenna device 100.

The antenna device 100 works in a millimeter wave frequency band. Millimeter waves generally refer to electromagnetic waves having a relatively short wavelength, electromagnetic waves having a wavelength of 1 to 10 millimeters, and a corresponding frequency domain range is 30 to 300 GHz.

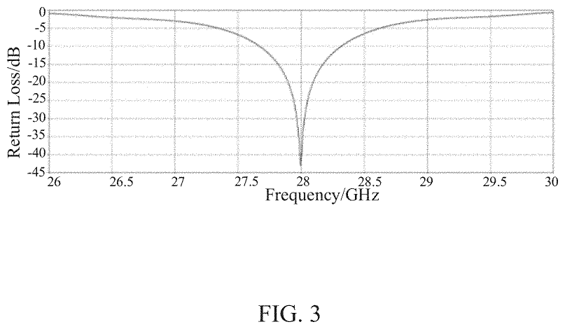

FIG. 3 is a diagram showing return loss of the antenna device in an embodiment of the present invention.

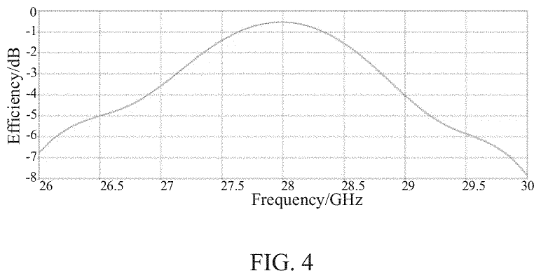

FIG. 4 is a diagram showing radiation efficiency of the antenna device in an embodiment of the present invention.

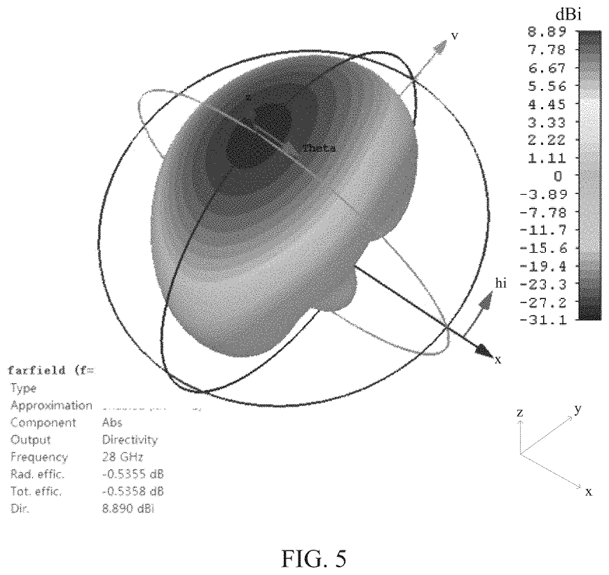

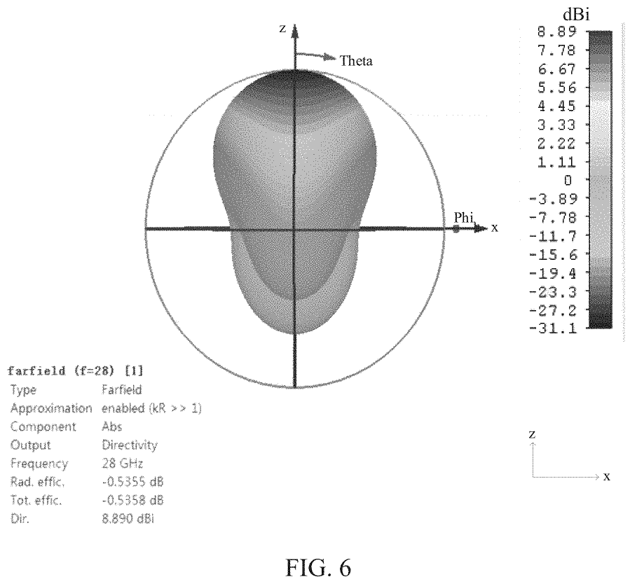

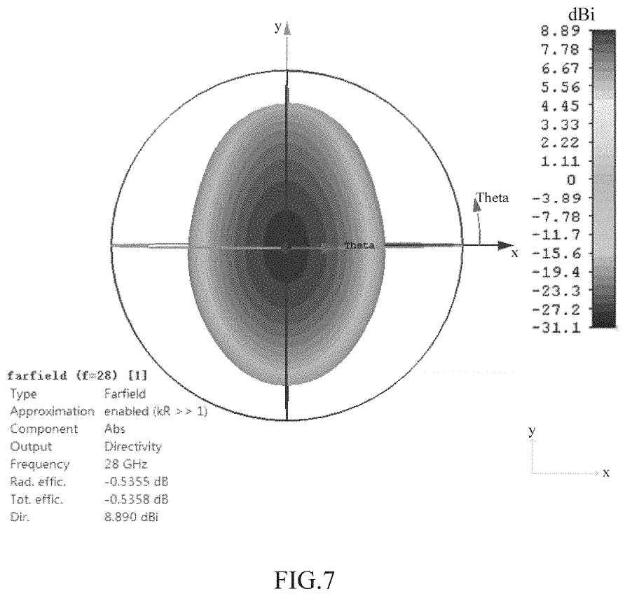

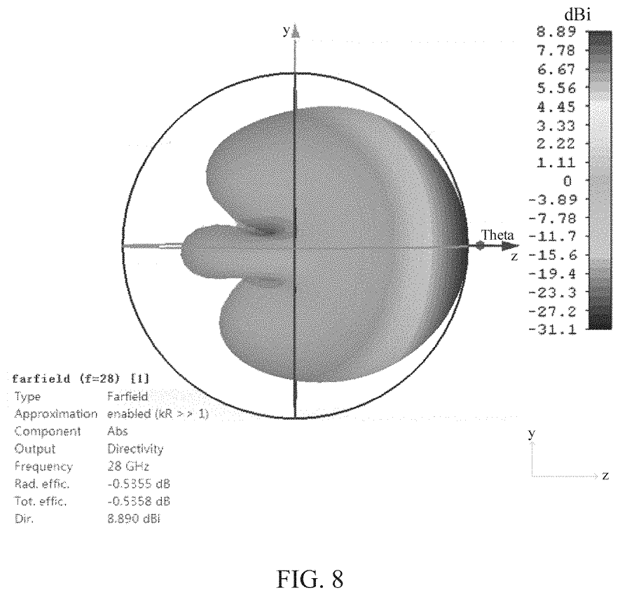

FIGS. 5 to 8 shows patterns of the antenna device in an embodiment of the present invention.

The above antenna device includes a substrate, a ground provided on one surface of the substrate, and an antenna provided on the other surface of the substrate; the antenna includes a first radiating portion, a second radiating portion, a one-to-two power divider and a feeding portion; the one-to-two power divider includes a third transmission wire connected to the feeding portion, a first transmission wire and a second transmission wire that extend in opposite directions from an end of the third transmission wire facing away from the feeding portion; the first radiating portion is provided with a first impedance adjusting groove, the other end of the first transmission wire is inserted into the first impedance adjusting groove and connected to the first radiating portion, and two symmetrically distributed first impedance adjusting sub-grooves are formed by inserting the other end of the first transmission wire into the first impedance adjusting groove; the second radiating portion is provided with a second impedance adjusting groove, the other end of the second transmission wire is inserted into the second impedance adjusting groove and connected to the second radiating portion, and two symmetrically distributed second impedance adjusting sub-grooves are formed by inserting the other end of the second transmission wire into the second impedance adjusting groove. It can be seen that the above antenna device has a simple structure and can meet the requirements for miniaturization of the terminal equipment, and the above antenna device can also achieve better directional radiation of the antenna and has a relatively wide radiation range in the radiation direction.

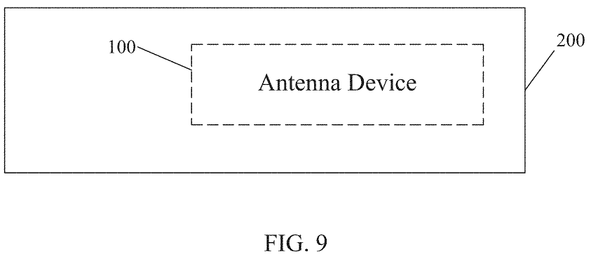

In an embodiment, an on-board equipment 200 is provided. As shown in FIG. 9, the on-board equipment 200 includes the antenna device 100 according to the above embodiments.

The above embodiments only express several implementation manners of the present invention, and the description thereof is relatively specific and detailed, but it should not be understood as a limitation of the patent scope of the present invention. It should be noted that, for those of ordinary skill in the art, a number of modifications and improvements can also be made without departing from the concept of the present invention, and all these fall within the protection scope of the present invention. Therefore, the protection scope of the present invention shall be subject to the appended claims.

What is claimed is:

1. An antenna device, comprising:
a substrate;
a ground provided on one surface of the substrate; and
an antenna provided on the other surface of the substrate and comprising a first radiating portion, a second radiating portion, a one-to-two power divider and a feeding portion,
wherein the one-to-two power divider comprises a first transmission wire, a second transmission wire, and a third transmission wire connected to the feeding portion, the first transmission wire and the second transmission wire extending in opposite directions from an end of the third transmission wire facing away from the feeding portion;
the first radiating portion is provided with a first impedance adjusting groove, and an end of the first transmission wire is inserted into the first impedance adjusting groove and connected to the first radiating portion, to form two symmetrically distributed first impedance adjusting sub-grooves; and
the second radiating portion is provided with a second impedance adjusting groove, and an end of the second transmission wire is inserted into the second impedance adjusting groove and connected to the second radiating portion, to form two symmetrically distributed second impedance adjusting sub-grooves.

2. The antenna device as described in claim 1, wherein the substrate is a PCB substrate.

3. The antenna device as described in claim 2, wherein a material of the PCB substrate is a millimeter wave dielectric material.

4. The antenna device as described in claim 3, wherein the PCB substrate is an RO4835T laminated board.

5. The antenna device as described in claim 2, wherein the PCB substrate has a thickness smaller than or equal to 1 mm.

6. The antenna device as described in claim 1, wherein the first impedance adjusting sub-groove is square or rectangular, and the second impedance adjusting sub-groove is square or rectangular.

7. The antenna device as described in claim 1, wherein the first radiating portion is square or rectangular, and the second radiating portion is square or rectangular.

8. The antenna device as described in claim 1, wherein the antenna device operates in a millimeter wave frequency band.

9. An on-board equipment, comprising the antenna device as described in claim 1.
